(19) United States
(12) Patent Application Publication
(10) Pub. No.: US 2018/0196090 A1
(43) Pub. Date: Jul. 12, 2018

(54) METHOD FOR ACQUIRING SIGNALS

(71) Applicant: Robert Bosch GmbH, Stuttgart (DE)

(72) Inventor: Jochen Quante, Ludwigsburg (DE)

(21) Appl. No.: 15/847,002

(22) Filed: Dec. 19, 2017

(30) Foreign Application Priority Data
Jan. 9, 2017 (DE) 102017200161.5

(51) Int. Cl. G01R 19/25; G06F 13/36

(52) U.S. Cl. CPC G01R 19/2509; G06F 13/36

(57) ABSTRACT

A method for acquiring signals of a control unit, including the steps of ascertaining a program dependency graph from a program of the control unit, the nodes of the program dependency graph being the computational steps of the program, from which signals are obtained, and whose segments are the data and/or control dependencies between the computational steps; defining a set of signals, which includes a first subset of signals to be measured and a second subset of dependent signals; assigning nodes to the first subset on condition that a node represents a signal to be measured, if a node is situated at an incoming segment of the node, outside of the set of signals; measuring the signals of the first subset; and calculating the signals of the second subset on the basis of the measured signals of the first subset.

### CROSS REFERENCE

The present application claims the benefit under 35 U.S.C. § 119 of German Patent Application No. DE 102017200161.5 filed on Jan. 9, 2017, which is expressly incorporated herein by reference in its entirety.

### FIELD

The present invention relates to a method for acquiring signals of a control unit, as well as to a corresponding control unit.

### BACKGROUND INFORMATION

In order to be able to reproduce effects, which occur in a control unit, internal signals are recorded during the running time of the control unit. These signal characteristics may then be visualized and evaluated with the aid of analysis software.

In this context, the number of logged signals or variables is limited, since the storage requirement increases linearly with the number of signals to be measured. Consequently, first of all, the storage and communications requirement for the running time increases, and secondly, the volume of data to be transmitted also increases. Therefore, only a fraction of all available signals may be recorded. In addition, only certain signals may be measured, such as messages and measuring points. In particular, no local variables may be measured, since they do not have a fixed address in the control unit.

Thus, in the analysis of the measurements, it may occur that needed signals are not contained in the measurement file. In this case, a new measurement is requested in consideration of the missing signals. This generates considerable expenditure for the measuring, as also for the subsequent communication and the delayed availability. At present, the selection of the signals to be recorded is done manually and therefore depends considerably on the experience of the measurer.

### SUMMARY

A first aspect of the present invention relates to a method for acquiring signals of a control unit, including the steps of ascertaining a program dependency graph from a program of the control unit, the nodes of the program dependency graph being the computational steps of the program, from which signals are obtained, and whose segments are the data and/or control dependencies between the computational steps; defining a set of signals, which includes a first subset of signals to be measured and a second subset of dependent signals; assigning nodes to the first subset on condition that a node represents a signal to be measured, if a further node is situated at an incoming segment of the node, outside of the set of signals; measuring the signals of the first subset; and calculating the signals of the second subset on the basis of the measured signals of the first subset. Using the method, a minimal number of signals is measured, by which the complete reconstruction of all of the further signals is subsequently carried out. Therefore, first of all, the data volume of the measurement is reduced; secondly, it is ensured that all of the signals needed for an evaluation are available. In addition, state variables that are currently unmeasurable may be made available. In this manner, the number of signals that are actually to be measured is efficiently reduced.

In one technically advantageous, specific embodiment of the example method according to the present invention, the nodes of the second subset are assigned on condition that the nodes at all incoming segments inside the set of signals are calculable. In this manner, for example, the technical advantage is achieved, that an alternative decision criterion for assignment may be used, and that the original assignment may be checked.

In a further technically advantageous, specific embodiment of the method, the assigning is carried out for all of the nodes inside the set of signals. In this manner, for example, the technical advantage is achieved, that all of the nodes may be uniquely assigned to one or the other subset.

In a further technically advantageous, specific embodiment of the method, the program dependency graph is ascertained statically or dynamically from the program. In the case of a static determination, for example, the technical advantage is achieved, that the time for implementing the method decreases. In the case of a dynamic determination, for example, the technical advantage is achieved, that a current program dependency graph may always be ascertained, for example, after a program update of the control unit.

In a further technically advantageous, specific embodiment of the method, the measured signals are stored in a measurements record. In this manner, for example, the technical advantage is achieved, that the dependent signals may be calculated at a later time or at a different location.

In a further technically advantageous, specific embodiment of the method, the measurements record is stored in a nonvolatile memory. In this manner, for example, the technical advantage is achieved, that the dependent signals may also continue to be calculated after an interruption of the power supply.

In a further technically advantageous, specific embodiment of the method, the step of measuring is based on measuring a current or a voltage of the specific signal at the respective computational step. In this manner, for example, the technical advantage is achieved, that suitable signals are obtained for further computation. The control unit may include an interface, in order to acquire these data. For example, a memory may be read out at the memory locations, which include the signals.

A second aspect of the present invention relates to a control unit, including a determination device for ascertaining a program dependency graph from a program of the control unit, the nodes of the program dependency graph being computational steps of the program, from which signals are obtained, and whose segments are the data and/or control dependencies between the computational steps; a definition interface for defining a set of signals, which includes a first subset of signals to be measured and a second subset of dependent signals; an assignment device for assigning nodes to the first subset on condition that a node represents a signal to be measured, if a node is situated at an incoming segment of the node, outside of the set of signals; a measuring tool for measuring the signals of the first subset; and a computational device for calculating the signals of the second subset on the basis of the measured signals of the first subset. The same technical advantages are achieved by the control unit as by the method according to the first aspect.

In one technically advantageous, specific embodiment of the control unit, the control unit includes a nonvolatile memory for storing a measurements record of the measured signals. In this manner, for example, the technical advantage is achieved, that the complete set of signals may also be calculated at a later time.

A third aspect of the present invention relates to a computer program, which may be loaded into the memory of a digital computer and includes the software code sections, by which the method according to the first aspect may be executed when the computer program runs on a computer. The same technical advantages are achieved by the computer program as by the method according to the first aspect.

Exemplary embodiments of the present invention are shown in the figures and are described below in further detail.

### BRIEF DESCRIPTION OF THE DRAWINGS

FIG. 1 shows a block diagram of an example method.

FIG. 2 shows a program dependency graph.

FIG. 3 shows a schematic view of an example control unit.

FIG. 4 shows a sequence of the example method.

### DETAILED DESCRIPTION OF EXAMPLE EMBODIMENTS

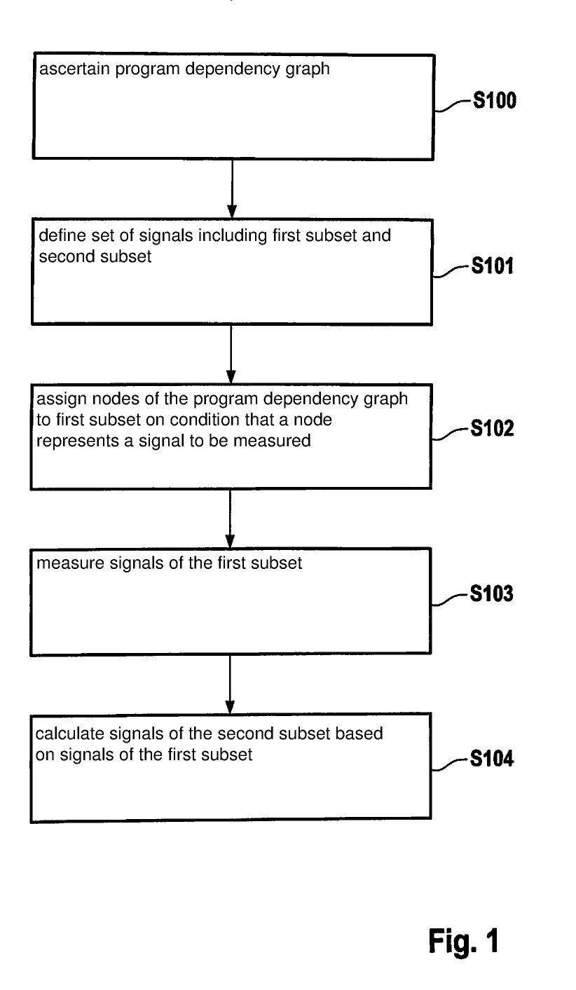

FIG. 1 shows a block diagram of an example method for acquiring signals of a control unit. The control unit is, for example, a control unit for engine control, which may potentially acquire a plurality of measured variables. A program of the control unit is used for evaluating and processing these measured variables further. In a plurality of computational steps, the program calculates one or more output signals from a plurality of input signals.

Consequently, each computational step generates, as an output, a further internal signal, which is processed further, using a further computational step.

In general, the control unit may be used for controlling any other device. The program of the control unit may be represented by a program dependency graph (program dependence graph). The determination of signals of the control unit, to be acquired, is carried out on the basis of this program dependency graph. The signals, which must be known for the calculation of a given set of dependent signals, may be determined automatically with the aid of the program dependency graph.

To that end, in step S100, the program dependency graph is initially ascertained from the program of the control unit. The nodes of the program dependency graph represent the internal computational steps of the program, from which the specific signals are obtained. The segments of the program dependency graph represent the data and/or control dependencies between the computational steps.

In step S101, a set of signals is defined, which includes a first subset of signals to be measured and a second subset of dependent signals. The signals of the second subset may be calculated from the signals of the first subset.

In step S102, nodes of the program dependency graph are assigned to the first subset on condition that a node represents a signal to be measured, when a subordinate node is situated at an incoming segment of the node, outside of the set of signals, and the node therefore has an incalculable segment.

In step S103, the signals of the first subset are measured with the aid of a suitable measuring tool. Subsequently, in step S104, the signals of the second subset are calculated on the basis of the measured signals of the first subset. This is possible, since the dependencies between the signals of the first subset and the signals of the second subset are known. First of all, this minimizes the number of signals to be measured, and secondly, it is ensured that nevertheless, all of the necessary information items are retained. This solves a technical problem that, first of all, during a later evaluation, no signals are missing, and therefore, no unnecessary, multiple measurements and recursions are required. Secondly, the scope of the measured signals may be decreased by the program dependency graph. A further technical advantage is the availability of state variables previously unmeasurable.

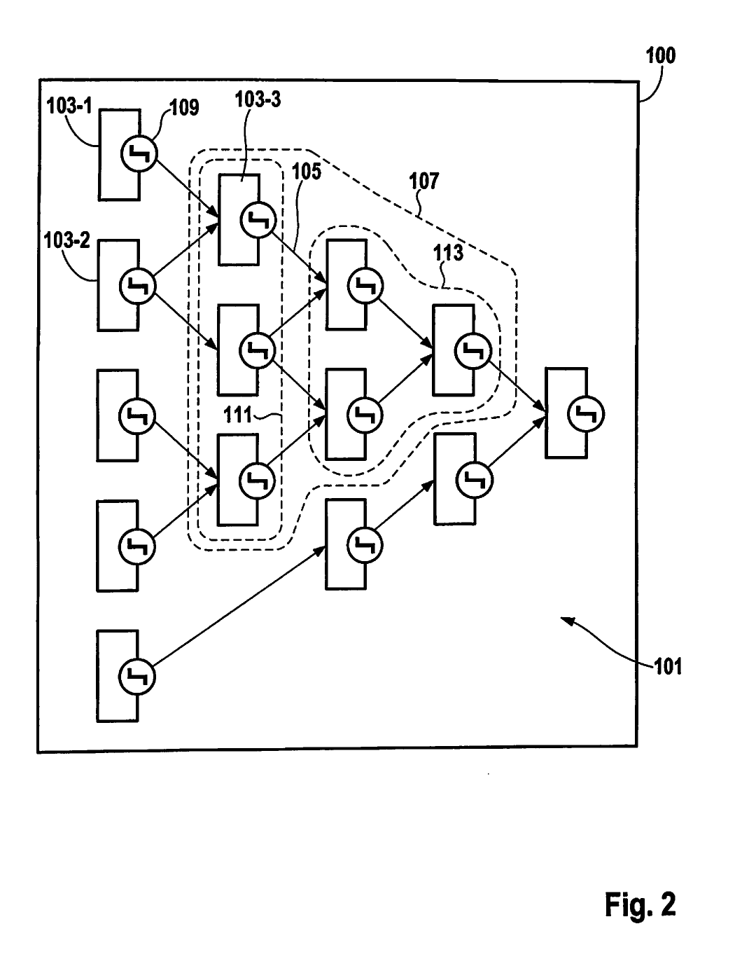

FIG. 2 shows an exemplary program dependency graph 101 of control unit 100, including data dependencies via segments 105 between nodes 103. Program dependency graph 101 is constructed on the basis of a control flow graph of the individual computational steps of the program. According to this, nodes 103 represent computational steps for signals 109 of the program of control unit 100.

At the same time, nodes 103 of the control flow graph form the nodes 103 of program dependency graph 100. Accordingly, the output signals of node 103-3 are dependent on the input signals of nodes 103-1 and 103-2. Two types of dependencies between nodes 103 may be derived from the interpretation by a program interpreter, of the significance of the computational steps belonging to nodes 103.

A data dependency exists between two nodes 103-1 and 103-3, if the other node 103-3 uses a variable, which was assigned a value in the one node 103-1, and a path exists in the control flow graph from the one node 103-1 to the other node 103-3 without the variable being reassigned a value.

A control dependency exists between two nodes 103-1 and 103-3, if one node 103-1 determines the execution of the other node 103-3. In this case, there is a path in the control flow graph from the one node 103-1 to the other node 103-3, and the one node 103-1 is a control flow node. In structured programs, for example, the computational steps after a condition (IF-instruction) or a loop element are dependent on the preceding condition. Therefore, the preceding condition represents a control flow node, on which the further execution of the program depends. In programs having arbitrary jumps, further cases are to be considered.

Thus, program dependency graph 101 describes the dependencies between individual computational steps of the program. A node 103, that is, a computational step for an internal signal, may be calculated, when nodes 103 are calculable at all incoming segments 103. Through the individual computational steps of the program, internal signals 109 are acquired as the output of the respective computational step.

Nodes 103 of program dependency graph 101 represent the individual computational steps of the program, and segments 105 of program dependency graph 101 represent the data and control dependencies between the computational steps. For example, the computational steps each include a multiplication, a division, a subtraction, an addition, an OR operation, an AND operation, or any other arithmetic operation, in which one or more output values are calculated from input values. The efficiency of the signal acquisition may be increased with the aid of program dependency graph 101.

Initially, set 107 of all of the desired signals 109 to be received is specified. This specification of the set of desired signals 109 may be carried out by a user. First of all, this set of signals 107 includes a subset 111 of nodes 103, i.e., computational steps, whose signals 109 may not be calculated, since the dependencies of nodes 103 lie outside of selected set of signals 107. Secondly, this set of signals 107 includes a subset 113 of nodes 103, whose signals 109 may be calculated due to the known dependencies inside of set of signals 107.

For program dependency graph 101, it is true that a node 103, i.e., a computational step, is calculable if nodes 103 are calculable at all incoming segments 105. By following the segments in program dependency graph 101, it may therefore be determined if a node 103 belongs to subset 111 or subset 113. If a node 103 is not calculable at all incoming segments, then this node belongs to subset 111. If a node is calculable at all incoming segments, then it belongs to subset 113.

After the assignment of nodes 103 to individual subsets 111 and 113, signals 109 of nodes 103 of the one subset 111 are measured explicitly, since these are not calculable. Signals 109 of nodes 103 of the other subset 113 are calculated, since the dependencies necessary for them are known.

Thus, program dependency graph 101 is used, in order to ascertain optimal subset 111 of the signals 109 to be measured, from set 107 of desired signals 109. The actual measurement of these signals 109 of first subset 111 is then carried out. After that, the program interpreter is used, in order to calculate the dependent signals 109 of second subset 113 now still missing, from measured signals 109 of subset 111.

This produces the technical advantage, that a minimal number of signals 109 may be measured, from which, however, the complete reconstruction of all remaining signals 109 may still be carried out subsequently.

When all measured signals 109 are covered, the program interpreter is able to ascertain dependent signals 109 of subset 113 from measured signals 109 of subset 111, to the extent that the respective input variables are completely known. The program interpreter cannot ascertain a result for parts of the program, which include unassigned inputs. In this respect, the program is interpreted with the aid of partial evaluation, to the extent that this is possible with the given variable assignment.

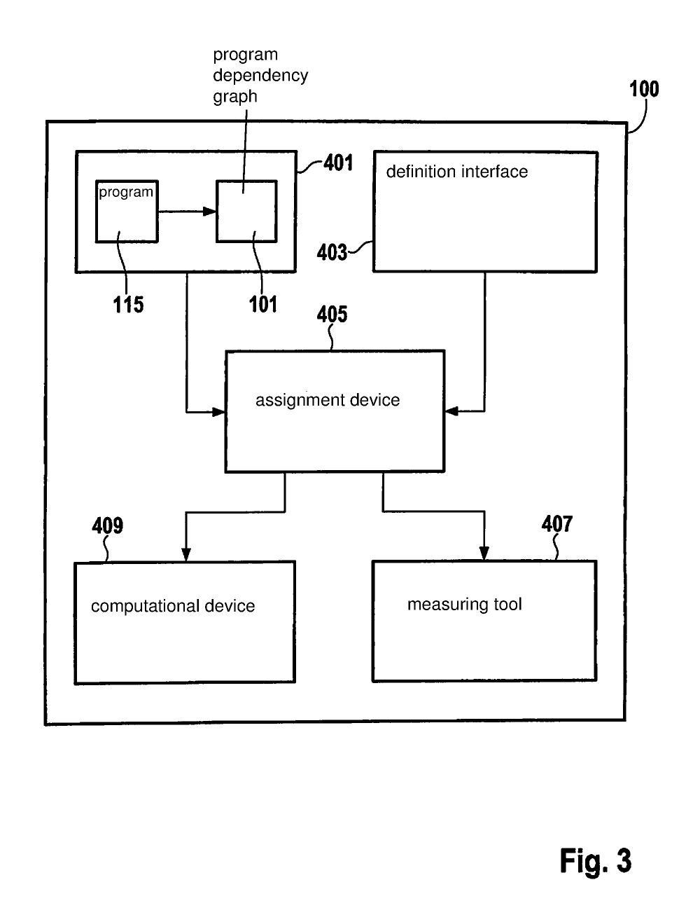

FIG. 3 shows a schematic view of control unit 100. Control unit 100 includes a determination device 401 for ascertaining program dependency graph 101 from program 115 of control unit 100. The ascertainment of program dependency graph 101 from program 115 of control unit 100 may be carried out one time in a static manner, or dynamically after an update of program 115.

A definition interface 403 of control unit 100 is used for defining desired set of signals 107, which includes first subset 111 of signals 109 to be measured and second subset 113 of dependent signals 109. Definition interface 403 is formed, for example, by an electronic interface or a program interface.

An assignment device 405 is used for assigning nodes 103 of program dependency graph 101 inside set of signals 107, to the first subset 111, on condition that a node 103 then represents a signal 109 to be measured, if at least one subordinate node 103 is situated at an incoming segment 105 of node 103, outside of set of signals 107, and may therefore not be calculated.

A measuring tool 407 of control unit 100 is used to measure signals 109 of first subset 111. For this purpose, the measuring tool picks off signals 109 at suitable points, for example, after the respective program steps or inside of an electronic circuit. A computational device 409 of control unit 100 is used for calculating signals 109 of second subset 113 on the basis of measured signals 109 of first subset 111.

Determination device 401, definition interface 403, assignment device 405, measuring tool 407, and computational device 409 may be formed by hardwired, digital circuits, which are adapted to execute the specific functions, such as application-specific integrated circuits (ASIC). However, determination device 401, definition interface 403, the assignment device, measuring tool 407, and computational device 409 may also be implemented by program modules, which are implemented with the aid of a processor of control unit 100.

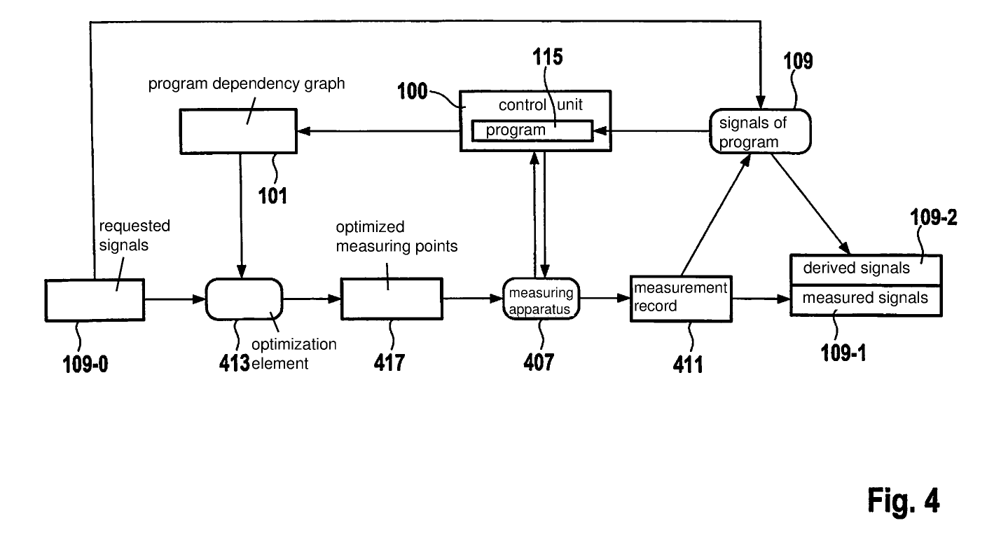

FIG. 4 shows a sequence of the method for acquiring signals 109-0, using control unit 100. With the aid of program dependency graph 101, an optimization element 413 ascertains optimal subset 111 of the signals 109-1 to actually be measured. To that end, program dependency graph 101 is derived one time, in advance, from program 115 of control unit 100. In the case of the actual measurement, corresponding signals 109-1 are recorded during operation of control unit 100, using a suitable measuring apparatus 407.

The additional, desired, but not measured signals 109-2 are then calculated and updated by program interpreter 415. To that end, program interpreter 415 is executed in program 115 of control unit 100, using measured signals 109-1. In this manner, all of the values of dependent signals 109-2 may be calculated. According to one design from program dependency graph 101, among them are also all of the desired measuring points.

In this manner, a user may continuously obtain the measured values for precisely the signals 109-0 requested. The present invention combines the technology of a program interpreter 415 and a program dependency graph 101 with measurements at control unit 100, in order to optimize them. Using control unit 100, it is possible to completely derive all of the desired signals 109 of set of signals 107 in an efficient manner with the aid of program interpreter 415. Subsequently, a program interpreter interprets program 115 of control unit 100 amid partial variable assignment.

The following algorithm may be used for calculating a minimum subset 111 of signals to be measured 109:
1. The user-specified input of set 107 of requested signals 109, which are intended to be measured, for example, all of the signals 109 of a function, follows as an input.
2. The following designations are possible (in combination, as well) for each individual node 103 in program dependency graph 101:
   a. Measurement desired (from request)
   b. Measurement possible (is given)
   c. Calculation possible
   d. Value needed (either by measurement or by calculation)
   e. Measurement necessary as a result of the algorithm.
   At the beginning, no node 103 is marked in program dependency graph 101 of control unit 100.
3. Desired or needed signals 109 are designated as 2.a) and 2.d) in program dependency graph 101.
4. Measurable signals 109 are designated as 2.b) in the program dependency graph.
5. The ability to calculate non-measurable nodes 103 is ensured as follows. The following applies for each non-measurable, desired node 103, i.e., for 2.a) and not 2.b):
   a. Follow segments 105 in program dependency graph 101 in the reverse direction.
   b. Mark all of the obtainable nodes 103 as 2.d), ending at measurable nodes 2.b).
6. Remove unnecessary measuring points as follows. The following holds for each measurable and needed node 103, i.e., for 2.b) and 2.d):
   a. If all input segments 105 lead, even transiently, over a plurality of segments 105, to nodes 103 of program dependency graph 101 that are designated by 2.b) and 2.d), then designate the nodes 103 as 2.c).
7. Optionally, subset 111 of nodes 103 to be measured may be further optimized with the aid of program dependency graph 101, in order to obtain optimized measuring points 417.
8. All nodes 103 that are designated by 2.b) and 2.d) and not 2.c) are subsequently marked with 2.e). In program dependency graph 101, these nodes 103 represent subset 111 of nodes 103 to be measured and, therefore, of signals 109-1 to be measured.

These signals 109-1 to be measured are actually measured by a measuring tool 407, and a corresponding measurements record 411, such as an electronic file, is generated. The electronic file may include a sequence of measuring points and be stored in control unit 100. On the basis of this measurements record 411, derived signals 109-2 may be calculated from measured signals 109-1.

Measuring tool 407 includes, for example, one or more current-measuring circuits for measuring a current, or voltage-measuring circuits for measuring a voltage.

Measuring tool 407 may also be used for reading a random access memory (RAM), in which signals 109 are stored in digital form. Signals 109 may also be stored in a nonvolatile memory, such as a hard disk or a USB stick, in order that they are retained, even after an interruption of a power supply.

The structure of this algorithm on program dependency graph 101 ensures that all desired signals 109-2 may actually be calculated by program interpreter 109 from measured signals 109-1. During the derivation of program dependency graph 101, loops may be rolled out and function requests may be used as required, that is, replaced by their implementation.

The method may be used in all areas, in which measurement data are acquired on operating control units 100. This relates to, in particular, function developers and applications engineers. Above all, in the communication of these groups, the present invention may aid in improving and accelerating the sequences, since complete and efficient acquisition of all required signals 109 with reduced technical expenditure is ensured.

The method represented in FIG. 4 illustrates an exemplary specific embodiment of the method, including the corresponding main components, and clarifies how these main components contribute to achieving the technical objective of measuring a minimum number of signals and reducing the quantity of data.

However, the range of protection of the present invention is given by the claims and is not limited by the features explained in the description or shown in the figures. Therefore, the method may be improved further within the scope of the claims, in order to increase the efficiency of the method.

All of the features explained and shown in connection with individual specific embodiments of the present invention may be provided in different combinations in the subject matter of the present invention, in order to simultaneously achieve their advantageous effects.

What is claimed is:

1. A method for acquiring signals of a control unit, comprising:
ascertaining a program dependency graph from a program of the control unit, nodes of the program dependency graph being computational steps of the program, from which signals are obtained, and segments of the program dependency graph are at least one of data dependencies and control dependencies, between the computational steps;
defining a set of signals, which includes a first subset of signals to be measured and a second subset of dependent signals;
assigning nodes to the first subset on condition that a node represents a signal to be measured, if a further node is situated at an incoming segment of the node, outside of the set of signals;
measuring the signals of the first subset; and
calculating the signals of the second subset based on the measured signals of the first subset.

2. The method as recited in claim 1, wherein the nodes of the second subset are assigned on condition that the nodes are able to be calculated at all incoming segments within the set of signals.

3. The method as recited in claim 1, wherein the assigning is carried out for all nodes within the set of signals.

4. The method as recited in claim 1, wherein the program dependency graph is ascertained from the program one of statically or dynamically.

5. The method as recited in claim 1, wherein the measured signals are stored in a measurements record.

6. The method as recited in claim 1, wherein the measurements record is stored in a nonvolatile memory.

7. The method as recited in claim 1, wherein the step of measuring is based on measuring a current or a voltage of the specific signal at a respective computational step.

8. A control unit, comprising:
a determination device for ascertaining a program dependency graph from a program of the control unit, nodes of the program dependency graph being the computational steps of the program, from which signals are obtained, and whose segments are at least one of data dependencies and control dependencies, between the computational steps;
a definition interface for defining a set of signals, which includes a first subset of signals to be measured and a second subset of dependent signals;
an assignment device for assigning nodes to the first subset on condition that a node represents a signal to be measured, if a further node is situated at an incoming segment of the node, outside of the set of signals;
a measuring tool for measuring the signals of the first subset; and
a computational device for calculating the signals of the second subset on the basis of the measured signals of the first subset.

9. The control unit as recited in claim 8, wherein the control unit includes a nonvolatile memory for storing a measurements record of the measured signals.

10. A non-transitory computer-readable memory of a digital computer on which is stored a computer program including software code sections for acquiring signals of a control unit, the computer program, when executed by the computer, causing the computer to perform:
ascertaining a program dependency graph from a program of the control unit, nodes of the program dependency graphs being computational steps of the program, from which signals are obtained, and whose segments are at least one of data dependencies and control dependencies, between the computational steps;
defining a set of signals, which includes a first subset of signals to be measured and a second subset of dependent signals;
assigning nodes to the first subset on condition that a node represents a signal to be measured, if a further node is situated at an incoming segment of the node, outside of the set of signals;
measuring the signals of the first subset; and
calculating the signals of the second subset based on the measured signals of the first subset.
